(19) United States
(12) Patent Application Publication
(10) Pub. No.: US 2026/0068396 A1
(43) Pub. Date: Mar. 5, 2026

(54) EMISSIVE OPTOELECTRONIC DEVICE WITH IMPROVED COLOR CONVERSION EFFICIENCY AND METHOD FOR MANUFACTURING SAME

(71) Applicant: COMMISSARIAT A L'ENERGIE ATOMIQUE ET AUX ENERGIES ALTERNATIVES, PARIS (FR)

(72) Inventors: Stéphane ALTAZIN, GRENOBLE CEDEX 09 (FR); Bastien MIRALLES, GRENOBLE CEDEX 09 (FR); Nicolas MICHIT, GRENOBLE CEDEX 09 (FR); Clément BALLOT, GRENOBLE CEDEX 09 (FR)

(73) Assignee: COMMISSARIAT A L'ENERGIE ATOMIQUE ET AUX ENERGIES ALTERNATIVES, PARIS (FR)

(21) Appl. No.: 19/314,508

(22) Filed: Aug. 29, 2025

(30) Foreign Application Priority Data
Aug. 30, 2024 (FR) FR2409293

(51) Int. Cl. H10H 29/851; H10H 29/01; H10H 29/14; H10H 29/80; H10K 59/38; H10K 59/80; H10K 102/00

(52) U.S. Cl. CPC H10H 29/8515; H10H 29/011; H10H 29/0361; H10H 29/14; H10H 29/8325; H10K 59/38; H10K 59/80518; H10K 2102/351

(57) ABSTRACT

The invention relates to a light-converting optoelectronic device comprising light-emitting diodes and conversion pads (40). Spacer portions (23) that are conductive and transparent, are located between the reflective portion (22) and the lower conductive portion (31) of the converting luminous pixels (Px_{ac}) only or of the non-converting luminous pixels (Px_{sc}) only. Moreover, the thickness (e_{31.opt}) of the lower conductive portions (31) and the thickness (e_{23.opt}) of the spacer portions (23) are predefined so as to maximize: in the non-converting luminous pixels (PX_{sc}), an extraction efficiency of the emitted light from the light emitting diode; and in the converting luminous pixels (PX_{ac}), a coupling efficiency of the light emitted by the active portion (32) with optical modes supported in the conversion portion (40).

### TECHNICAL FIELD

The field of the invention is that of optoelectronic devices comprising a color-conversion luminous pixel array. The invention is particularly applicable in display screens and image projectors.

### PRIOR ART

Optoelectronic devices comprising an array of luminous pixels formed by identical light-emitting diodes exist, in which devices certain pixels comprise color-conversion portions. An array of luminous pixels of different colors is thus obtained; such optoelectronic devices can thus form display screens or image projection systems.

In such an optoelectronic device, each color-conversion luminous pixel comprises one or more light-emitting diodes associated with a color conversion portion. In order to obtain luminous pixels suitable for emitting light radiation of different colors, for example blue, green or red, the light-emitting diodes can be adjusted to each emit the same light, for example a blue light, and the green and red pixels comprise light conversion portions suitable for at least partially absorbing incident blue light and, in response, emitting green light or red light.

The light-emitting diodes are therefore preferably identical to one another, and emit light of the same wavelength. They can be formed from a semiconductor material comprising elements from column III and column V of the periodic table, such as a III-V compound, in particular gallium nitride (GaN), indium gallium nitride (InGaN) or aluminum gallium nitride (AlGaN). They are arranged so as to form an array of light-emitting diodes having a front face from which the generated light is transmitted. Furthermore, the light-emitting diodes can comprise a reflective electrode on the rear face side, and a transparent electrode on the front face side.

The light conversion portions can be formed from a binder matrix comprising particles of a photoluminescent material such as, in particular, yttrium aluminum garnet (YAG) activated by the cerium ion YAG:Ce. The photoluminescent particles can also be quantum dots, i.e. in the form of semiconductor nanocrystals, the quantum confinement of which is substantially three-dimensional.

FIG. 1 is a diagrammatic, partial, cross-sectional view of an optoelectronic device 1 according to one example of the prior art. It comprises a driver chip 10, a front face whereof comprises conductive portions 11 for biasing and driving the light-emitting diodes. It comprises an optoelectronic chip 20 which rests on the driver chip 10 and which is electrically connected thereto. It comprises the light-emitting diode array. Each light-emitting diode comprises a diode structure 30 formed of a semiconductor stack of two doped semiconductor portions 31, 33 between which an active portion 32 is located. It rests on a lower reflective electrode, formed in this case by an electrical contact portion 21 and by a reflective portion 22. Finally, certain diodes are covered by light conversion portions 40 and define color-converting luminous pixels Px_{ac}, whereas the diodes not covered by the conversion portions 40 define non-color-converting luminous pixels Px_{sc}.

There is a need to improve the color conversion efficiency. To do this, one solution may be to increase the thickness of the conversion portions. However, this can lead to technological difficulties, especially when the pixel pitch is low.

### DISCLOSURE OF THE INVENTION

The aim of the invention is to at least partially overcome the drawbacks of the prior art, and more particularly to provide an optoelectronic device, and the method for manufacturing same, the color conversion efficiency of which device is improved in converting luminous pixels Px_{ac}, while maintaining good performance in non-converting luminous pixels PX_{sc}.

The invention therefore relates to an optoelectronic device for converting light, which device comprises:
an array of light-emitting diodes, each light-emitting diode comprising, in this order: a lower reflective electrode formed of a contact portion then of a reflective portion; a diode structure formed of a lower conductive portion of the same thickness for all diodes in the array, of an active light-emitting portion, then of an upper conductive portion; and an upper electrode;
color conversion pads, covering certain light-emitting diodes of the array, and defining color-converting luminous pixels; light-emitting diodes not covered by conversion pads defining non-color-converting luminous pixels.

According to the invention, the optoelectronic device comprises spacer portions, made of an electrically conductive material that is transparent to the emitted light, which portions are located between the reflective portion and the lower conductive portion of the converting luminous pixels only, or of the non-converting luminous pixels only.

Moreover, the thickness of the lower conductive portions and the thickness of the spacer portions are predefined such that:
each active portion of the non-converting luminous pixels is spaced apart from the reflective portion by a same optimal distance h_{sc.opt} maximizing, in the non-converting luminous pixels, a parameter representative of an extraction efficiency of the light emitted by the active portion from the light-emitting diode; and
each active portion of the converting luminous pixels is spaced apart from the reflective portion by the same optimal distance h_{ac.opt} maximizing, in the converting luminous pixels, a parameter representative of a coupling efficiency of the light emitted by the active portion with optical modes supported in the conversion portion.

Some preferred but non-limitative aspects of this optoelectronic device are as follows.

The reflective portions of the diode array can have the same thickness.

The contact portions can have a thickness that differs between the converting luminous pixels and the non-converting luminous pixels, and can have a lower face that is coplanar from one contact portion to the next.

The lower conductive portions can have a lower face that is coplanar from one lower conductive portion to the next.

The active portions can be coplanar.

The lower conductive portion can be made of at least one semiconductor material.

The lower conductive portion can comprise a first sublayer made of at least one semiconductor material, located on the active portion side, and a second sublayer made of an electrically conductive material transparent to the emitted light, located on the reflective portion side.

The light-emitting diodes can be inorganic or organic.

The invention further relates to a method for manufacturing an optoelectronic device according to any one of the preceding features, which method comprises the following steps:
determining an optimal thickness e_{31.opt} of the lower conductive portions, based on a predetermined function expressing:
   according to a first possibility: a variation of the parameter representative of the extraction efficiency, as a function of the thickness e₃₁ of the lower conductive portion, in non-converting luminous pixels, the optimal value e_{31.opt} maximizing the parameter representative of the extraction efficiency, such that the distance h_{sc.opt} is obtained; or
   according to a second possibility: a variation of the parameter representative of the coupling efficiency of the light emitted by the active portion with optical modes supported in the conversion portion, in converting luminous pixels, the optimal value e_{31.opt} maximizing the parameter representative of the coupling efficiency, such that the distance h_{ac.opt} is obtained;
determining an optimal thickness e_{23.opt} of the spacer portions, given a predetermined optimal thickness e_{31.opt}, based on a predetermined function expressing:
   according to the first possibility: a variation of the parameter representative of the coupling efficiency, as a function of the thickness e₂₃ of the spacer portion, the spacer portions being located only in the converting luminous pixels, the optimal thickness e_{23.opt} maximizing the parameter representative of the coupling efficiency, such that the distance h_{ac.opt} is obtained;
   according to the second possibility: a variation of the parameter representative of the extraction efficiency, as a function of the thickness e₂₃ of the spacer portion, the spacer portions being located only in the non-converting luminous pixels, the optimal thickness e_{23.opt} maximizing the parameter representative of the extraction efficiency, such that the distance h_{sc.opt} is obtained;
producing the light-emitting diode array, such that: the lower conductive portions of the diode array have the same determined optimal thickness e_{31.opt}; and the spacer portions have the same determined optimal thickness e_{23.opt}.

During the step of determining the optimal thickness e_{31.opt} and according to the second possibility, the optimal value e_{31.opt} can be determined so as to maximize the parameter representative of the coupling efficiency and to minimize a parameter representative of a second coupling efficiency of the light emitted by the active portion with optical modes supported in the conversion portion and which can be extracted from the diode.

During the step of determining the optimal thickness e_{23.opt} and according to the first possibility, the optimal value e_{23.opt} can be determined so as to maximize the parameter representative of the coupling efficiency and to minimize a parameter representative of a second coupling efficiency of the light emitted by the active portion with optical modes supported in the conversion portion and which can be extracted from the diode.

The step of producing the diode array can comprise the following steps:
producing a stack formed of the upper conductive portions, the active portions, and the lower conductive portions having the optimal thickness e_{31.opt};
producing the spacer portions having the optimal thickness e_{23.opt}, on the lower conductive portions of the converting luminous pixels in the first possibility or in the non-converting luminous pixels according to the second possibility;
producing the reflective portions, then the contact portions.

The method may comprise the following steps:
following the step of producing the diode array, transferring the structure obtained to a driver chip;
producing the upper electrodes on the upper conductive portions;
producing the conversion portions.

### BRIEF DESCRIPTION OF THE DRAWINGS

Other aspects, aims, advantages and characteristics of the invention will become apparent upon reading the following detailed description of preferred embodiments thereof, provided as a non-limiting example, and made with reference to the accompanying drawings wherein:

FIG. 1, already described, is a diagrammatic, partial, cross-sectional view of an optoelectronic device with an array of light-emitting diodes and with color conversion, according to an example of the prior art;

FIG. 2A is a diagrammatic, partial, cross-sectional view of an optoelectronic device according to a first embodiment, wherein the spacer portions are located only in the color-converting luminous pixels;

FIG. 2B is a diagrammatic, partial, cross-sectional view of an optoelectronic device according to a second embodiment, wherein the spacer portions are located only in the non-color-converting luminous pixels;

FIG. 3A is a diagrammatic, partial, cross-sectional view of a non-color-converting luminous pixel of an optoelectronic device according to the first embodiment and similar to that of FIG. 2A;

FIG. 3B illustrates an alternative embodiment, depending on the thickness of the lower conductive portion of the light-emitting diode in FIG. 3A, of the distribution of the power of the radiation emitted by the active portion of the diode and dissipated in different optical modes associated with the luminous pixel;

FIG. 4A is a diagrammatic, partial, cross-sectional view of a color-converting luminous pixel of an optoelectronic device according to the first embodiment and similar to that of FIG. 2A;

FIG. 4B illustrates an alternative embodiment, depending on the thickness of the spacer portion of the light-emitting diode in FIG. 4A, of the distribution of the power of the radiation emitted by the active portion of the diode and dissipated in different optical modes associated with the luminous pixel;

FIG. 5A to 5H illustrate various steps of a method for manufacturing an optoelectronic device according to the first embodiment and that is similar to that of FIG. 2A.

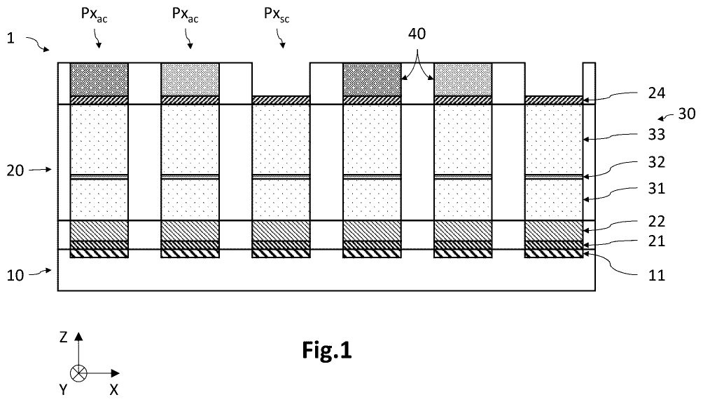

### DETAILED DISCLOSURE OF PARTICULAR EMBODIMENTS

In the figures and in the following description, the same references represent identical or similar elements. Furthermore, the different elements are not represented to scale so as to improve the clarity of the figures. Moreover, the different embodiments and alternatives are not mutually exclusive and could be combined together. Unless stated otherwise, the terms “substantially”, “about”, and “in the order of” mean to within 10%, and preferably to within 5%. Moreover, the terms “between . . . and . . . ” and equivalents mean that the bounds are included, unless specified otherwise.

The invention relates to a color-converting optoelectronic device and to the method for manufacturing same. The optoelectronic device comprises a light-emitting diode array, of which at least a part is covered by color conversion pads, so as to form an array of luminous pixels of different colors. The optoelectronic device can be, for example, a display screen or an image projector. The light-emitting diodes can be inorganic (LED) or organic (OLED) diodes.

As described below, the size of the light-emitting diodes is determined, in terms of distance between the active portion and the underlying reflective portion, so as to maximize, in the non-color-converting luminous pixels Px_{sc}, the extraction efficiency of the light from the diode, and in the color-converting luminous pixels Px_{ac}, the coupling efficiency of the light in optical modes supported by the conversion portions (thus optimizing the absorption efficiency by the conversion portions, and therefore the conversion efficiency).

For this purpose, the thickness e₃₁ of the lower conductive portions of the light-emitting diodes (which can be, for example, a doped semiconductor layer in the case of LEDs or a charge carrier transport layer in the case of OLEDs) is determined, and the thickness e₂₃ of spacer portions, which are located between a reflective portion of the lower reflective electrode and the lower conductive portion of the diode structure, is determined. These spacer portions are present either only in the converting luminous pixels Px_{ac} (first embodiment), or only in the non-converting luminous pixels Px_{sc} (second embodiment).

Thus, each active portion of the non-converting luminous pixels Px_{sc} is spaced apart from the reflective portion by a same predefined distance h_{sc.opt} maximizing, in the non-converting luminous pixels Px_{sc}, the extraction of the light emitted by the active portion from the light-emitting diode. Furthermore, each active portion of the converting luminous pixels Px_{ac} is spaced apart from the reflective portion by a same predefined distance h_{ac.opt} maximizing, in the converting luminous pixels Px_{ac}, the coupling of the light emitted by the active portion with optical modes supported in the conversion portion.

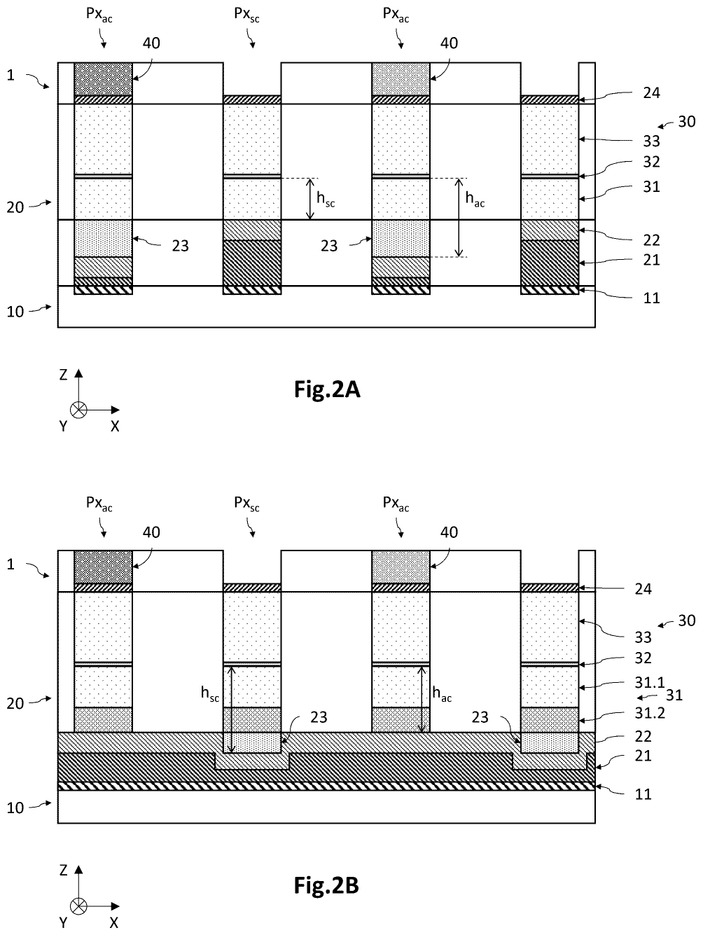

FIG. 2A is a diagrammatic, partial, cross-sectional view of an optoelectronic device according to the first embodiment wherein the spacer portions 23 are located only in the color-converting luminous pixels Px_{ac}, and FIG. 2B is a diagrammatic, partial, cross-sectional view of an optoelectronic device according to the second embodiment wherein the spacer portions 23 are located only in the non-color-converting luminous pixels Px_{sc}.

In these examples, the optoelectronic device comprises an array of luminous pixels of the RGB type (red, green, blue). Each pixel is formed of at least one light-emitting diode (in this case one diode per pixel). Other types of luminous pixels are possible, for example of the RGB-IR type (Red, Green, Blue, InfraRed).

Hereinafter, and in the rest of the description, a direct three-dimensional orthogonal reference frame XYZ is defined, wherein the X and Y axes form a main plane in which the diode array extends, and wherein the Z axis is oriented from the driver chip towards the front face of the optoelectronic device. In the description below, the terms “lower” and “upper” should be understood as relating to a positioning that increases as the distance from the driver chip in the direction +Z increases.

The optoelectronic device 1 can comprise a driver chip 10, to which the optoelectronic chip 20 is assembled and electrically connected at its rear face. The driver chip 10 can provide a mechanical support function for the optoelectronic chip 20, and contributes to electrically biasing the diode array. It can comprise a CMOS-type control circuit, and has electrical connection portions 11 that lie flush with its upper face and come into contact with the lower electrodes of the diodes, and in this case with the contact portions 21. The electrical connection portions 11 are, in this case, separate from each other. Alternatively (see FIG. 2B), this can be the same electrical connection layer (also given the reference numeral 11): in this case, the upper electrodes 24 are separate from each other so as to be able to activate the diodes selectively.

The optoelectronic device 1 comprises an optoelectronic chip 20, which is formed of the light-emitting diode array and light conversion portions 40.

The light-emitting diode array has a rear face, through which it is assembled and connected to the driver chip 10, and a front face, opposite the rear face, through which the light emitted by the active portions 32 is transmitted out of the diode. The light is then transmitted in the environment of the diode, for example in air, in the case of non-converting luminous pixels Px_{sc}, or is transmitted in the conversion portions 40 in the case of converting luminous pixels Px_{ac}.

In general, the light-emitting diodes are formed from a stack of the following, in the order given:
a lower reflective electrode 21, 22;
a diode structure 30 formed of a lower conductive portion 31, a light-emitting active portion 32, then an upper conductive portion 33; and
an upper electrode 24.

In the remainder of the description, the upper electrode 24 is transparent and preferably completely covers the upper face of the upper conductive portion 33. Alternatively, it can be made of an opaque material and may only cover a lateral surface of the upper face of the portion 33 while leaving an uncovered central surface.

As described below, in this first embodiment, the diodes of only the converting luminous pixels Px_{ac} comprise a spacer portion 23 that makes it possible to adjust the distance h_{ac} between the active portion 32 and the underlying reflective portion 22. The diodes of the non-converting luminous pixels Px_{sc} do not comprise such spacer portions 23.

The diodes are preferably structurally identical, so that the emitted light radiation is identical from one diode to another in terms of wavelength. In this example, the diodes are suitable for emitting blue light radiation, i.e. for which the emission spectrum has an intensity peak at a wavelength between about 440 nm and 490 nm.

In this example, the diodes are of the inorganic type (LED). The lower conductive portion 31 and upper conductive portion 33 are, in this case, semiconductor portions doped according to opposite conductivity types. By way of example, the lower conductive portion 31 can be p-doped, and the upper conductive portion 33 is thus n-doped. This semiconductor stack can be made from the same semiconductor compound, for example based on a III-V compound such as GaN, InGaN, AlGaN. In this example, the lower conductive portion 31 is p-GaN and the upper conductive portion 33 is n-GaN. The active portion 32 from which the light radiation is emitted comprises quantum wells for example made of InGaN.

In the case where the diodes are of the organic type (OLED), the lower conductive portion 31 and upper conductive portion 33 can be, respectively, for example, hole transport portions (HTLs) and electron transport portions (ETLs).

The portions 31, 32 and 33 of the diodes are, in this case, distinct from one diode to the next. They are coplanar, in that the portions 31 of the diodes are coplanar to each other, the portions 32 are coplanar to each other, and the portions 33 are coplanar to each other. The upper face of the portion 33 and the lower face of the portion 31 are planar and parallel to each other.

Furthermore, the lower conductive portion 31 is, in this case, made of one or more semiconductor materials (in this case p-GaN). However, as described below with reference to FIG. 2B, the lower conductive portion 31 can be formed of a semiconductor portion 31.1 (located on the active portion 32 side) and an underlying conductive portion 31.2 (located on the reflective portion 22 side). The conductive portion 31.2 makes it possible to adjust the distance between the active portions 32 and the underlying reflective portions 22 (distance h_{sc} in the non-converting luminous pixels Px_{sc}, and distance h_{ac} in the converting luminous pixels Px_{ac}).

The light-emitting diodes comprise lower reflective electrodes 21, 22 in electrical contact with the lower conductive portions 31. They are formed of a contact portion 21 and a reflective portion 22. The contact portion 21 can be made of one or more materials such as Ti, Ni, Pt, Sn, Au, Ag, Al, Pd, W, Pb, Cu, AuSn, TiSn or an alloy of these elements. It can thus be a stack of Ti and TIN sub-layers. The contact portion 22 is made of at least one material reflecting the light emitted by the active portion, for example aluminum or silver.

In this example, the contact portions 21 and the reflective portions 22 are separate from one diode to the next. In other words, the contact portions 21 are physically separated from one diode to the next, as are the reflective portions 22. However, as illustrated in FIG. 2B, the contact portions 21 can be continuously joined so as to form one and the same layer. This is also the case for the reflective portion 22.

The reflective portion 22 is made of the same one or more materials from one diode to the next and has the same thickness. The contact portion 21 is made of the same one or more materials from one diode to the next, but the thickness thereof differs between its thickness in the converting luminous pixels Px_{ac} and its thickness in the non-converting luminous pixels Px_{sc}, such that the lower face of the contact portions 21 is coplanar from one contact portion to the other.

It should be noted that the diodes are separated from each other in the XY plane by one or more pixelation materials. It can be formed of a first thin insulating passivation layer, then of a second thin reflective layer, for example a thin aluminum or silver layer, so as to limit the optical crosstalk between the diodes, and of a filling material that fills the remaining space between the diodes. Other configurations are possible.

Moreover, the sidewalls of the diodes in this case are vertical; however, alternatively, they can be inclined by an angle, for example between −30° and +30° relative to the Z axis, and preferably between −10° and +10°. The choice of the angle of inclination of the sidewalls can help improve the coupling efficiency of the light in the conversion portions 40.

The light-emitting diodes in this case comprise transparent upper electrodes 24 which completely cover the underlying portion 33. They are made of at least one electrically conductive material that is transparent to the light radiation emitted by the active portions 32. They can be made of TCO, such as ITO (indium tin oxide), or even of one or more semi-transparent fine metal materials (e.g. Ag). In this example, the electrodes 24 are distinct from one diode to the next.

The optoelectronic chip 20 comprises light conversion portions 40, distinct from each other (physically separated in pairs, for example by air), and arranged facing certain diodes of the array so as to form color-converting luminous pixels Px_{ac}. These conversion portions 40 are suitable for at least partially converting incident light radiation of a first wavelength λ₁ into light radiation of a longer wavelength λ₂. By way of illustration, they can also be suitable for absorbing blue light, i.e. light for which the wavelength is between about 440 nm and 490 nm, and for emitting in the green, i.e. at a wavelength between about 495 nm and 560 nm, or even in the red, i.e. at a wavelength between 600 nm and 650 nm. Here, wavelength shall mean the wavelength at which the emission spectrum has an intensity peak.

The conversion portions 40 comprise photoluminescent particles which can be formed of at least one semiconductor compound, which can be chosen for example, from cadmium selenide (CdSe), indium phosphide (InP), indium gallium phosphide (InGaP), cadmium sulfide (CdS), zinc sulfide (ZnS), cadmium oxide (CdO) or zinc oxide (ZnO), cadmium zinc selenide (CdZnSe), zinc selenide (ZnSe) doped, for example, with copper or manganese, graphene or any other suitable semiconductor materials. The nanoparticles can also have a core/shell structure, such as CdSe/ZnS, CdSe/CdS, CdSe/CdS/ZnS, PbSe/PbS, CdTe/CdSe, CdSe/ZnTe, InP/ZnS or others. The particles can also have a perovskite crystal structure comprising atoms such as those listed for the nanoparticles, but also Cs, Mn or Br. The conversion portions 40 can have a thickness between 100 nm and 10 μm, for example in the order of 2 μm. As indicated above, the lateral border of the conversion portions 40 can be covered by a thin reflective layer, so as to orient the radiation in the direction +Z.

According to the invention, the light-emitting diodes are sized such that, in the non-color-converting luminous pixels Px_{sc}, the active portion 32 is spaced apart from the reflective portion 22 by a predefined optimal distance h_{sc.opt} that maximizes the extraction of light from the light-emitting diode. Furthermore, in the color-converting luminous pixels Px_{ac}, the active portion 32 is spaced apart from the reflective portion 22 by a predefined optimal distance h_{ac.opt} that maximizes the coupling of the light emitted by the active portion 32 with optical modes supported by the conversion portion 40.

For this purpose, lower conductive portions 31 having the same optimal thickness e_{31.opt} are produced in the non-color-converting luminous pixels Px_{sc} and the color-converting luminous pixels PX_{ac}; and spacer portions 23 of optimal thickness e_{23.opt} are placed, either in the non-color-converting luminous pixels Px_{sc} only (first embodiment), or in the color-converting luminous pixels PX_{ac} only (second embodiment).

Optical modes supported by the conversion portion 40 is understood to mean optical modes circulating in the diode structure 30 and in the conversion portion 40, and whose fraction of optical power is denoted f_{p1.ac}. These are optical modes that can be extracted from the diode (in this case in air) and whose power fraction is denoted f_{p1.ace}, and optical modes that are trapped and cannot be extracted from the diode and whose power fraction is denoted f_{p1.ac.p}. Either way, the optical modes propagate in the conversion portion 40, and can be absorbed therein by the photoluminescent particles, which improves the conversion efficiency. The conversion efficiency is defined herein as the ratio of the intensity of the photoluminescence radiation emitted by the photoluminescent particles of the conversion portion 40 to the intensity of the electroluminescence radiation emitted by the active portion 32.

The spacer portions 23 are made of at least one electrically conductive material that is transparent at the wavelength of the diode. It can have the same refractive index as that of the lower conductive portion 31. It can be a conductive transparent oxide, such as a conductive metal oxide (ITO, ZnO, AZO, etc.). In the case of an OLED, the material can be an organic material allowing for the transport of holes or electrons. They are located between the reflective portion 22 and the lower conductive portion 31 of the converting luminous pixels Px_{ac} only (first embodiment) or of the non-converting luminous pixels Px_{sc} only (second embodiment).

The distances h_{sc} and h_{ac} are defined as being the distance along the axis Z between, on the one hand, an upper plane passing through the active portion 32 where most of the radiative recombinations of the electron-hole pairs are located, and, on the other hand, the upper face of the reflective portion 22. The upper plane can pass through the middle of the active portion 32. Alternatively, in the case shown here where the active portion 32 has a negligible thickness, the upper plane can be considered to pass at the interface between the active portion 32 and the lower conductive portion 31.

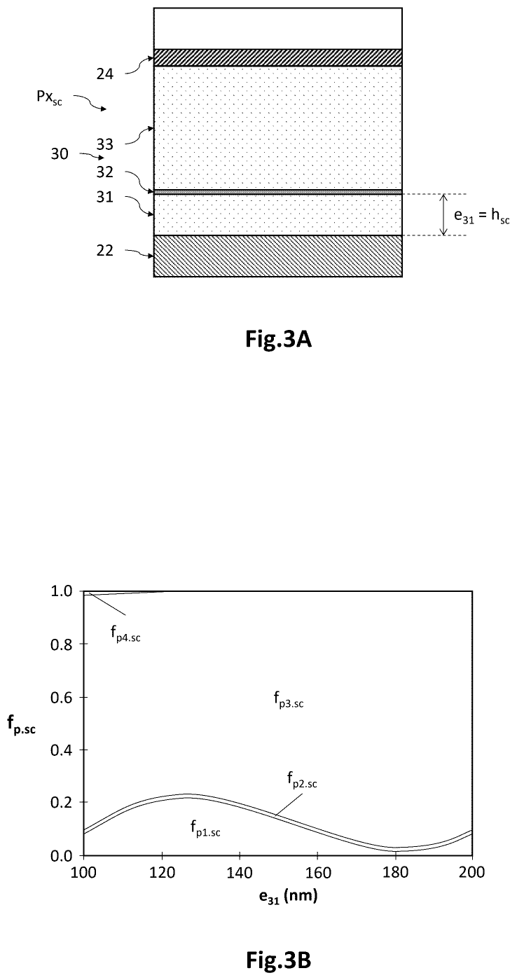

With reference to FIGS. 3A and 3B, a step of determining the optimal distance h_{sc.opt}, and more precisely the optimal thickness e_{31.opt}, will now be described for the non-converting luminous pixels Px_{sc} of an optoelectronic device 1 similar to that in FIG. 2A, therefore according to the first embodiment wherein the spacer portions 23 are located only in the color-converting luminous pixels PX_{ac}.

FIG. 3A is a diagrammatic, partial, cross-sectional view of a diode of a non-converting luminous pixel Px_{sc} of an optoelectronic device 1 similar to that of FIG. 2A.

The non-converting luminous pixel Px_{sc} is formed of: a reflective portion 22, in this case made of aluminum with an infinite thickness; a diode structure 30 formed of a lower semiconductor portion 31 made of p-doped GaN and having a thickness e₃₁, an active portion (not shown, negligible thickness), and an upper semiconductor portion 33 made of n-doped GaN and having a thickness of 400 nm. Finally, a transparent electrode 24 made of ITO and having a thickness of 40 nm covers the upper portion 33. The diode environment is air. The sidewalls are covered with a thin reflective layer (not shown) to limit optical crosstalk.

FIG. 3B illustrates an alternative embodiment, depending on the thickness e₃₁ of the lower conductive portion 31, of the distribution of the power f_{p.sc} of the radiation emitted by the active portion 32 of the diode and dissipated in different optical modes associated with the luminous pixel PX_{sc}.

It should be recalled that the external quantum efficiency (or light emitting efficiency, denoted EQE or ηₑₓₜ) corresponds to the ratio of the light flux emitted by the active portion to the electrical power injected. It is equal to the product of the internal quantum efficiency (IQE or ηᵢₙₜ) and the extraction efficiency (ηₒᵤₜ). This extraction efficiency ηₒᵤₜ depends in particular on the distribution of the power of the radiation emitted by the active portion of the diode and dissipated in different optical modes associated with the luminous pixel. Several optical modes can be distinguished: those extracted from the diode (power fraction f_{p1.sc}), in this case in air; those absorbed in the diode (power fraction f_{p2.sc}); those guided in the diode (power fraction f_{p3.sc}); and finally those coupled by evanescence and absorbed in or at the interface of the lower electrode (power fraction f_{p4.sc}).

This variation in the distribution of the dissipated power as a function of the thickness e₃₁ of the lower semiconductor portion 31 can be calculated by numerical resolution of the Maxwell equations. Thus, a function is obtained expressing a change in the parameter f_{p1.sc} representative of the extraction efficiency, as a function of the thickness e₃₁ of the lower conductive portion 31, in the non-converting luminous pixels Px_{sc}. Reference can be made here in particular to the article by Benisty et al. entitled Impact of planar microcavity effects on light extraction—Part I: Basic concepts and analytical trends, IEEE J. Quantum Electron., vol. 34, no. 9, pp. 1612-1631, 1998, and the article by Schmidt et al. entitled Emitter Orientation as a Key Parameter in Organic Light-Emitting Diodes, Phys. Rev. Applied 8, 037001 (2017).

This distribution of the dissipated power depends on the refractive indices and thicknesses of the portions of the diode, the distance h_{sc} and the considered orientation of the emitting dipole. It should be recalled here that the light radiation emitted in the active portion by radiative recombination of the electron-hole pairs corresponds to the electrical dipole radiation emitted by a dipole that oscillates harmoniously along the axis of its dipole moment u (also referred to as TDMV or Transition Dipole Moment Vector). It is assumed here that the dipole is oriented horizontally (in this case parallel to the main plane of the optoelectronic chip).

Here we are looking at the fraction f_{p1.sc} of the optical power that is extracted from the diode, so in this case in air. The optimum value e_{31.opt} of the thickness e₃₁ is chosen to maximize this power fraction f_{p1.sc}. In this example, the optimum thickness e_{31.opt} is in the order of 125 nm. Thus, in the diode array, all the lower conductive portions 31 have the same thickness e_{31.opt} of 125 nm. Thus, the non-converting luminous pixels Px_{sc} have a maximized extraction efficiency.

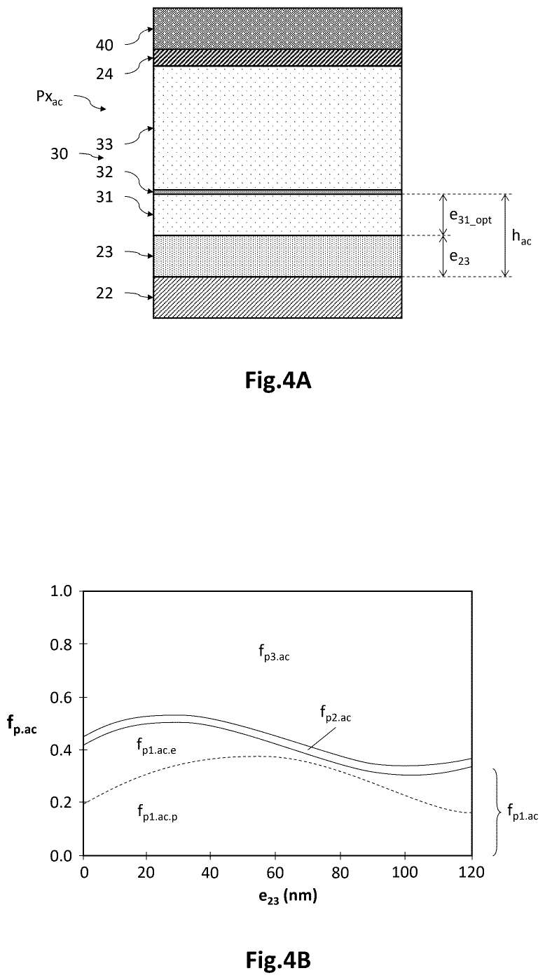

A step of determining the optimal distance h_{ac.opt} for the converting luminous pixels Px_{ac} of the optoelectronic device 1 similar to that of FIG. 2A will now be described with reference to FIGS. 4A and 4B.

FIG. 4A is a diagrammatic, partial, cross-sectional view of a diode of a converting luminous pixel Px_{ac} of the optoelectronic device 1 similar to that of FIG. 2A.

The converting luminous pixel Px_{ac} has the stacking structure similar to that of the pixel of FIG. 3A, and is distinguished by the presence of an ITO spacer portion 23 located between the reflective portion 22 and the lower semiconductor portion 31. It is also distinguished by the presence of a conversion portion 40 that completely covers the upper face of the transparent upper electrode 24. Moreover, the lower semiconductor portion 31 has the optimum thickness e_{31.opt} of 125 nm determined during the previous step.

FIG. 4B illustrates an alternative embodiment, depending on the thickness e₂₃ of the spacer portion 23, of the distribution of the power f_{p.ac} of the radiation emitted by the active portion 32 of the diode and dissipated in different optical modes associated with the luminous pixel Px_{ac}.

In this case, the power fraction f_{p1.ac} corresponds to the optical power dissipated in optical modes supported by the diode structure 30 and by the conversion portion 40. This power fraction f_{p1.ac} comprises two components: on the one hand, a first part f_{p1.ac.e} which contains the optical modes that can propagate in air; and on the other hand, a second part f_{p1.ac.p} which does not contain the optical modes that can couple in air due to total internal reflection between the conversion portion 40 and the air: it therefore relates to the optical modes supported and trapped in the diode structure 30 and the conversion portion 40.

In other words, the first component f_{p1.ac.e} corresponds to any light emitted by the active portion 32 which can propagate in the conversion layer 40, this light being able to be transmitted in the air after having passed through the conversion layer 40. As for the second component f_{p1.ac.p}, it corresponds to the light emitted by the active portion 32 and able to propagate in the conversion layer 40 but not allowing propagation in air: the light is then trapped in the diode structure 30 and in the conversion portion 40 by total internal reflection.

Several strategies are possible to maximize the coupling of the light with the conversion portions 40.

Thus, in the case where the conversion portion 40 is thick, for example at least equal to 5 μm, the optimum value e_{23.opt} of the thickness e₂₃ of the spacer portions 23 that maximizes the power fraction f_{P1.ac} can be chosen. More specifically, the optical modes that circulate in the conversion portion 40 can be absorbed and converted therein, whether they are optical modes that can be extracted in the air (f_{p1.ac.e} fraction) or trapped optical modes (f_{p1.ac.p} fraction). In this example, the optimum thickness e_{23.opt} can be chosen to equal about 20 nm.

Alternatively, in the case where the conversion portion 40 is thin, for example at most equal to 4 μm, the optimum value e_{23.opt} of the thickness e₂₃ of the spacer portions 23 can be chosen to maximize the power fraction f_{P1.ac.p}. More specifically, preference will be given to the optical modes that circulate and are trapped in the diode structure 30 and the conversion portion 40. This improves the chances of absorption and therefore the conversion efficiency. In this example, the optimum thickness e_{23.opt} can be chosen to equal about 45-50 nm.

Moreover, effort can be made to maximize the conversion efficiency (hence to maximize the fraction f_{p1.ac} or the fraction f_{p1.ac.p}), while also minimizing the flow of light emitted by the active portion 32 and not or little absorbed by the conversion portion 40 (hence to minimize the fraction f_{p1.ac.e}). In particular, this makes it possible to avoid having to use a blue filter (in the case where the active portion 32 emits blue light) in the converting luminous pixels Px_{ac}. This is particularly advantageous when the conversion portion 40 is thin (hence when the fraction f_{p1.ac.p} is maximized). In this example, the optimal thickness e_{23.opt} can be chosen to equal about 75-80 nm, which makes it possible to maximize the fraction f_{p1.ac.p} and to minimize the fraction f_{p1.ac.e}.

Thus, the optoelectronic device 1 according to the first embodiment has improved performance levels, due to the fact that the sizing of the light-emitting diodes, in terms of the thickness e₃₁ of the lower conductive portion 31 and the thickness e₂₃ of the spacer portion 23 (and thus in terms of the distances h_{sc} and h_{ac}), maximizes both the extraction efficiency in the non-converting luminous pixels Px_{sc} and the absorption efficiency (and thus the conversion efficiency) in the conversion portions 40 of the converting luminous pixels Px_{ac}. In particular, this makes it possible to avoid the need to produce conversion portions of too great thickness, and also makes it possible to develop optoelectronic devices with low pixel pitches.

Furthermore, as the lower conductive portions 31 have the same thickness e_{31.opt} and the distance h_{ac} is adjusted via the thickness e₂₃ of the spacer portions 23, there is therefore no need to locally modify the thickness e₃₁ of the lower conductive portions 31, which could result in deterioration of the internal quantum efficiency (IQE). Conductivity problems of p-doped GaN are also avoided.

Moreover, as indicated above, it is also possible to limit, in the converting luminous pixels PX_{ac}, the light flow emitted by the active portion 32 and not absorbed by the conversion portion 40. This avoids having to arrange a filter filtering the light emitted by the diodes (for example in this case a blue filter) in the converting luminous pixels Px_{ac}.

Thus, a method for manufacturing an optoelectronic device according to the first embodiment (wherein the spacer portions 23 are located only in the converting luminous pixels PX_{ac}), can comprise the following steps:
determining, for the non-converting luminous pixels Px_{sc}, an optimal thickness e_{31.opt} of the lower conductive portions 31, from a predetermined function expressing a variation of the parameter (fraction f_{p1.sc}) representative of the extraction efficiency as a function of the thickness e₃₁ of the lower conductive portion 31, the optimal thickness e_{31.opt} maximizing the parameter f_{p1.sc}; the distance h_{sc.opt} is thus obtained;
determining, for the converting luminous pixels Px_{ac} wherein the lower conductive portions 31 have the determined optimal thickness e_{31.opt}, an optimal thickness e_{23.opt} of the spacer portions 23, from a predetermined function expressing a variation of the parameter (fraction f_{p1.ac} or fraction f_{p1.ac.p}) representative of the coupling efficiency, as a function of the thickness e₂₃ of the spacer portion 23, the optimal thickness e_{23.opt} maximizing the parameter representative of the coupling efficiency; the distance h_{ac.opt} is thus obtained;
producing the light-emitting diode array, such that: the lower conductive portions 31 of the diode array (thus of the non-converting luminous pixels Px_{sc} as well as of the converting luminous pixels Px_{ac}) have the same determined optimal thickness e_{31.opt}; and the spacer portions 23 (located only in the converting luminous pixels Px_{ac}) have the same determined optimal thickness e_{23.opt}.

FIG. 2B is a diagrammatic, partial, cross-sectional view of an optoelectronic device 1 according to one example of the second embodiment.

The optoelectronic device 1 differs from that of FIG. 2A essentially in that the spacer portions 23 are disposed in the non-converting luminous pixels Px_{sc} only, and not in the converting luminous pixels Px_{ac}.

Moreover, in this example, the contact portions 21 and the reflective portions 22 each form the continuous layers from one diode to the next; however, they could be discontinuous as in FIG. 2A. The lower electrodes are therefore all brought to the same electrical potential, and the diodes can be activated selectively by biasing the upper electrodes independently of each other.

Moreover, in this example, the lower conductive layer 31 is formed of a sublayer 31.1 made of a semiconductor material, in this case p-GaN, and of a spacer sublayer 31.2 made of an electrically conductive material that is transparent to the light emitted by the active layer 32, for example in this case a TCO such as ITO.

A step of determining the optimal distance h_{ac.opt}, and more precisely the optimal thickness e_{31.opt}, will now be described for the converting luminous pixels Px_{ac} of an optoelectronic device 1 similar to that of FIG. 2B, therefore according to the second embodiment wherein the spacer portions 23 are located only in the non-color-converting luminous pixels Px_{sc}.

Firstly, a converting luminous pixel Px_{ac} is considered, and a variation is determined, according to the thickness e₃₁ of the lower conductive portion 31, in the distribution of the power f_{p.ac} of the radiation emitted by the active portion 32 of the diode and dissipated in different optical modes associated with the luminous pixel Px_{ac}.

We are interested herein in the optical power dissipated in optical modes supported by the conversion portion 40 (and by the diode structure 30). The optimal value e_{31.opt} of the thickness e₃₁ is chosen so as to maximize coupling with the conversion portion 40 (and therefore the conversion efficiency). As indicated above, the optimal thickness e_{31.opt} can be chosen to maximize the fraction f_{p1.ac} (if the conversion portion 40 is thick) or the fraction f_{p1.ac.p} (if the conversion portion 40 is thin). Effort can also be made to minimize the fraction f_{p1.ac.e} in order to limit the unabsorbed light flow in the conversion portion 40 and thus dispense with a blue filter.

A non-converting luminous pixel Px_{sc} is then considered and a variation, according to the thickness e₂₃ of the spacer portion 23, in the distribution of the power f_{p.sc} of the radiation emitted by the active portion 32 and dissipated in different optical modes associated with the luminous pixel Px_{sc} is determined. In this case, in the luminous pixels Px_{sc} and Px_{ac}, the lower conductive portions 31 have the optimal thickness e_{31.opt} that has just been determined.

Focus will now be placed on the optical power f_{p1.sc} extracted in air. The optimum value e_{23.opt} of the thickness e₂₃ is chosen so as to maximize the extraction of light from the diode, and thus maximize the fraction f_{p1.sc}, taking into account e_{31.opt}.

Thus, the optoelectronic device 1 according to the second embodiment also has improved performance levels, due to the fact that the sizing of the light-emitting diodes, in terms of the thickness e₃₁ of the lower conductive portion 31 and the thickness e₂₃ of the spacer portion 23 (and thus in terms of the distances h_{sc} and h_{ac}), also in this case maximizes the extraction efficiency in the non-converting luminous pixels Px_{sc} and the absorption efficiency (and thus the conversion efficiency) in the conversion portions 40 of the converting luminous pixels Px_{ac}.

Thus, a method for manufacturing an optoelectronic device according to the second embodiment (wherein the spacer portions 23 are located only in the non-converting luminous pixels Px_{sc}), can comprise the following steps:
determining, for the converting luminous pixels Px_{ac}, an optimal thickness e_{31.opt} of the lower conductive portions 31, from a predetermined function expressing a variation of a parameter (fraction f_{p1.ac} or fraction f_{p1.ac.p}) representative of the coupling efficiency as a function of the thickness e₃₁ of the lower conductive portion 31, the optimal thickness e_{31.opt} maximizing the parameter representative of the coupling efficiency; the distance h_{ac.opt} is thus obtained;
determining, for the non-converting luminous pixels Px_{ac} wherein the lower conductive portions 31 have the determined optimal thickness e_{31.opt}, an optimal thickness e_{23.opt} of the spacer portions 23, from a predetermined function expressing a variation of the parameter (fraction f_{p1.sc}) representative of the extraction efficiency, as a function of f_{p1.sc}; the optimal thickness e_{23.opt} maximizing the parameter f_{p1.sc}; the distance h_{sc.opt} is thus obtained;
producing the light-emitting diode array, such that: the lower conductive portions 31 of the diode array (thus of the non-converting luminous pixels Px_{sc} as well as of the converting luminous pixels Px_{ac}) have the same determined optimal thickness e_{31.opt}; and the spacer portions 23 (located only in the non-converting luminous pixels Px_{sc}) have the same determined optimal thickness e_{23.opt}.

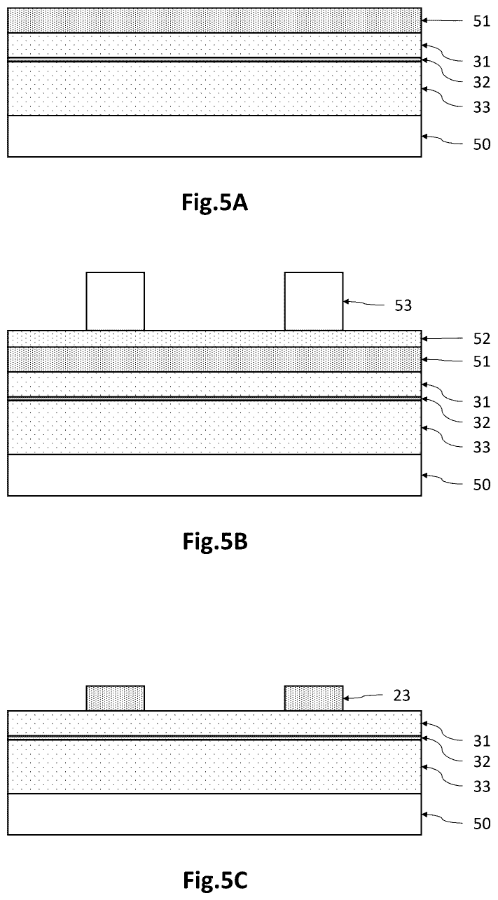

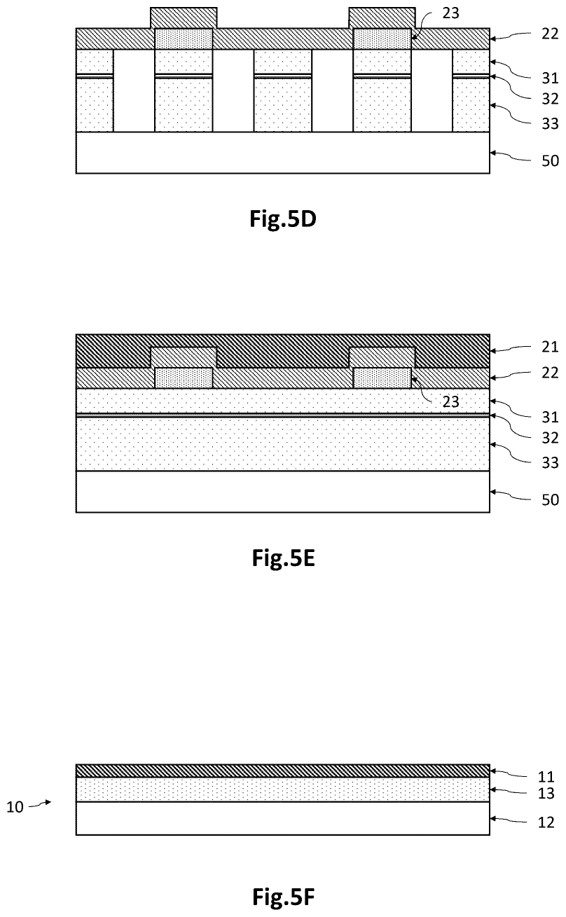

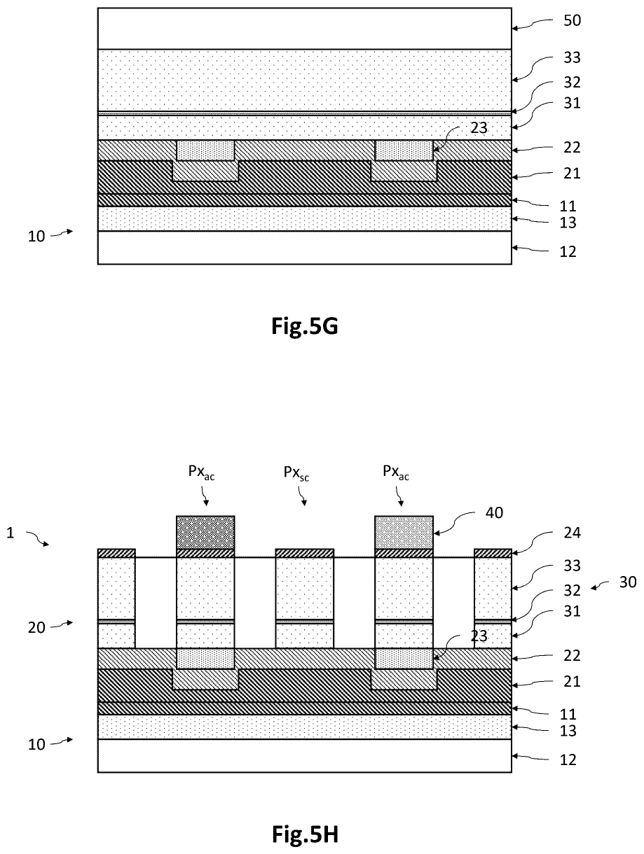

FIG. 5A to 5H illustrate steps of a method for manufacturing an optoelectronic device 1 according to an alternative of the first embodiment, therefore similar to that of FIG. 2A, but which differs therefrom in that the contact portion 21 and reflective portion 22 form continuous layers from one diode to the next.

With reference to FIG. 5A, a semiconductor stack formed of a first layer 33 of n-doped GaN, an active layer 32 comprising InGaN quantum wells, and a second layer 31 of p-doped GaN is produced by epitaxy, from a growth substrate 50 (in this case a silicon substrate and AlGaN buffer layers for adaptation of the mesh parameter). The p-GaN layer 31 has a thickness e_{31.opt}, in this case a thickness of 125 nm, such that the distance h_{sc} will have the optimal value h_{sc.opt}.

A spacer layer 51 is then deposited so as to cover the free face of the p-GaN layer 31. It has a thickness e_{23.opt}, in this case equal to about 20 nm or 45-50 nm, such that the distance h_{ac} will have the predetermined optimal value h_{ac.opt}. The material of the spacer layer 51 (and therefore of the spacer portions 23) is, in this case, a transparent conductive oxide (TCO) such as ITO. This is because it has good electrical contact and good adhesion on the p-GaN, good adhesion with the reflective layer 22 subsequently deposited, and good etching compatibility.

With reference to FIG. 5B, an oxide layer 52, for example a TEOS with a thickness in the order of a few hundred nanometers, is deposited so as to cover the free face of the spacer layer 51. Mask pads 53 are then produced with a view to producing the spacer portions.

With reference to FIG. 5C, the spacer portions 23 are produced. For this purpose, a first dry etching step (RIE) of the oxide layer 52 (not protected by the mask pads 53) can be carried out with a etch stop on the spacer layer 31. A stripping step is then carried out so as to remove the mask pads 33. Then, the spacer layer 31 not protected by the remaining oxide portions is etched locally, for example by wet etching with hydrochloric acid (HCl) with an etch stop on the p-GaN layer 31. Finally, etching to remove the oxide portions is carried out, for example by wet etching with hydrofluoric acid (HF). Spacer portions 23 are thus obtained and the p-GaN layer 31 has a free surface.

With reference to FIG. 5D, the reflective layer 22 is produced, in this case by deposition of an aluminum layer with a thickness of 100 nm. This layer 22 extends in contact with the free surface of the p-GaN layer 31 and covers the spacer portions 23.

With reference to FIG. 5E, the contact layer 21 is then produced. This is deposited on and in contact with the reflective layer 22. It can be a stack of a plurality of sublayers, such as, for example, a Ti bonding sublayer having a thickness of 10 nm, followed by a TiN barrier sublayer having a thickness of 40 nm, and finally a Ti contact/bonding sublayer having a thickness of 500 nm. A chemical-mechanical polishing step (CMP) is then carried out so as to make the upper face of the contact layer 21 planar.

With reference to FIG. 5F, a support substrate 10 is produced which mechanically supports and electrically connects the optoelectronic chip. It can form the driver chip 10 mentioned above. In this example, the support substrate 10 is formed by a stack of a silicon layer 12 (for example a silicon wafer), an upper oxide layer 13, and finally a conductive contact layer 11. This can be formed from a stack of a Ti sub-layer having a thickness of 5 nm, then of a TiN sub-layer having a thickness of 30 nm, and finally of a Ti sub-layer having a thickness of about 100 to 200 nm (after a chemical-mechanical polishing step).

With reference to FIG. 5G, assembly is carried out by transferring and direct Ti/Ti bonding of the structure of FIG. 5E onto the support substrate 10. More specifically, the two conductive layers 11 and 21 are brought into contact with one another.

With reference to FIG. 5H, the growth substrate 50 is removed, for example by grinding, followed by chemical etching, so as to release the upper face of the n-GaN layer 33. The diodes are then pixelated, then the upper electrodes 24 are produced, in this case from an electrically conductive and transparent material such as ITO. The arrangement thereof defines the luminous pixels. Finally, the conversion portions 40 are produced at the converting luminous pixels Px_{ac}.

Thus, an optoelectronic device 1 is obtained, the non-converting luminous pixels Px_{sc} whereof have an extraction efficiency maximized by the sizing of the distance h_{sc} and in this case of the thickness e₃₁ of the lower semiconductor layer 31, and the converting luminous pixels Px_{ac} whereof have a conversion efficiency maximized by the sizing of the distance h_{ac} and in this case of the thickness e₂₃ of the spacer portions 23 (taking into account the thickness e_{31.opt} of the layer 31). The performance of the optoelectronic device 1 is therefore optimized.

Particular embodiments have just been described. Different alternatives and modifications will become apparent to the person skilled in the art.

1. A light-converting optoelectronic device comprising:
an array of light-emitting diodes, each light-emitting diode comprising, in this order: a lower reflective electrode formed of a contact portion then of a reflective portion; a diode structure formed of a lower conductive portion of the same thickness for all diodes in the array, of an active light-emitting portion, then of an upper conductive portion; and an upper electrode;
color conversion pads, covering certain light-emitting diodes of the array, and defining color-converting luminous pixels; light-emitting diodes not covered by conversion pads defining non-color-converting luminous pixels;
wherein it comprises spacer portions, made of an electrically conductive material that is transparent to the emitted light, which portions are disposed between the reflective portion and the lower conductive portion of the converting luminous pixels only or the non-converting luminous pixels only;
and in that the thickness of the lower conductive portions and the thickness of the spacer portions are predefined such that:
each active portion of the non-converting luminous pixels is spaced apart from the reflective portion by the same optimal distance h_{sc.opt} maximizing, in the non-converting luminous pixels, a parameter representative of an extraction efficiency of the light emitted by the active portion from the light-emitting diode; and
each active portion of the converting luminous pixels is spaced apart from the reflective portion by the same optimal distance h_{ac.opt} maximizing, in the converting luminous pixels, a parameter representative of a coupling efficiency of the light emitted by the active portion with optical modes supported in the conversion portion.

2. The optoelectronic device according to claim 1, wherein the reflective portions of the diode array have the same thickness.

3. The optoelectronic device according to claim 1, wherein the thickness of the contact portions differs between the converting luminous pixels and the non-converting luminous pixels, and the lower face thereof is coplanar from one contact portion to the next.

4. The optoelectronic device according to claim 1, wherein the lower conductive portions have a lower face that is coplanar from one lower conductive portion to the next.

5. The optoelectronic device according to claim 1, wherein the active portions are coplanar.

6. The optoelectronic device according to claim 1, wherein the lower conductive portion is made of at least one semiconductor material.

7. The optoelectronic device according to claim 1, wherein the lower conductive portion comprises a first sublayer made of at least one semiconductor material, disposed on the active portion side, and a second sublayer made of an electrically conductive material that is transparent to the emitted light, disposed on the reflective portion side.

8. The optoelectronic device according to claim 1, wherein the light-emitting diodes are inorganic or organic.

9. A method for manufacturing the optoelectronic device according to claim 1, which method comprises the following steps:
determining an optimal thickness e_{31.opt} of the lower conductive portions, based on a predetermined function expressing:
according to a first possibility: a variation of the parameter representative of the extraction efficiency, as a function of the thickness e₃₁ of the lower conductive portion, in non-converting luminous pixels, the optimal value e_{31.opt} maximizing the parameter representative of the extraction efficiency, such that the distance h_{sc.opt} is obtained; or
according to a second possibility: a variation of the parameter representative of the coupling efficiency of the light emitted by the active portion with optical modes supported in the conversion portion, in converting luminous pixels, the optimal value e_{31.opt} maximizing the parameter representative of the coupling efficiency, such that the distance h_{ac.opt} is obtained;
determining an optimal thickness e_{23.opt} of the spacer portions, given a predetermined optimal thickness e_{31.opt}, based on a predetermined function expressing:
according to the first possibility: a variation of the parameter representative of the coupling efficiency, as a function of the thickness e₂₃ of the spacer portion, wherein the spacer portions are disposed only in the converting luminous pixels, the optimal thickness e_{23.opt} maximizing the parameter representative of the coupling efficiency, such that the distance h_{ac.opt} is obtained;
according to the second possibility: a variation of the parameter representative of the extraction efficiency, as a function of the thickness e₂₃ of the spacer portion, wherein the spacer portions are disposed only in the non-converting luminous pixels, the optimal thickness e_{23.opt} maximizing the parameter representative of the extraction efficiency, such that the distance h_{sc.opt} is obtained;
producing the light-emitting diode array, such that: the lower conductive portions of the diode array have the same determined optimal thickness e_{31.opt}; and the spacer portions have the same determined optimal thickness e_{23.opt}.

10. The manufacturing method according to claim 9, wherein:
during the step of determining the optimal thickness e_{31.opt} and according to the second possibility, the optimal value e_{31.opt} is determined so as to maximize the parameter representative of the coupling efficiency and to minimize a parameter representative of a second coupling efficiency of the light emitted by the active portion with optical modes supported in the conversion portion and which can be extracted from the diode;
during the step of determining the optimal thickness e_{23.opt} and according to the first possibility, the optimal value e_{23.opt} is determined so as to maximize the parameter representative of the coupling efficiency and to minimize a parameter representative of a second coupling efficiency of the light emitted by the active portion with optical modes supported in the conversion portion and which can be extracted from the diode.

11. The manufacturing method according to claim 9, wherein the step of producing the diode array comprises the following steps:
producing a stack formed of the upper conductive portions, the active portions, and the lower conductive portions having the optimal thickness e_{31.opt};
producing the spacer portions having the optimal thickness e_{23.opt}, on the lower conductive portions of the converting luminous pixels in the first possibility or in the non-converting luminous pixels according to the second possibility;
producing the reflective portions, then the contact portions.

12. The manufacturing method according to claim 11, comprising the following steps:
following the step of producing the diode array, transferring the structure obtained to a driver chip;
producing the upper electrodes on the upper conductive portions;
producing the conversion portions.
